(19) United States
(12) Patent Application Publication
(10) Pub. No.: US 2016/0268891 A1
(43) Pub. Date: Sep. 15, 2016

(54) METHOD AND APPARATUS FOR TRANSMISSION OF LOGICAL SIGNALS

(71) Applicant: Realtek Semiconductor Corp., Hsinchu (TW)

(72) Inventors: Gerchih (Joseph) Chou, San Jose, CA (US); Chia-Liang (Leon) Lin, Fremont, CA (US)

(21) Appl. No.: 14/641,474

(22) Filed: Mar. 9, 2015

(51) Int. Cl. H02M 3/07; H03K 3/017; H03K 5/1534; H03K 19/003; H03K 19/20

(52) U.S. Cl. CPC H02M 3/07; H03K 19/00346; H03K 19/20; H03K 5/1534; H03K 3/017

(57) ABSTRACT

In one embodiment, a method comprising receiving a logical signal; driving a source voltage at a first circuit node using a driver circuit; generating an impulsive edge signal by detecting a transition of the logical signal; converting the impulsive edge signal into an impulsive charge pump current using a charge pump circuit; injecting the impulsive charge pump current into the first circuit node; transmitting the source voltage to a second circuit node via a transmission line; and terminating the second circuit node with a load.

### BACKGROUND OF THE INVENTION

1. Field of the Invention

The present invention generally relates to transmission of logical signals.

2. Description of Related Art

Persons of ordinary skill in the art understand terms and basic concepts related to microelectronics that are used in this disclosure, such as “voltage,” “current,” “signal,” “load,” “logical signal,” “inverter,” “circuit node,” “transmission line,” “characteristic impedance,” “input impedance,” “output impedance,” “current source,” “current sink,” “switch,” “parasitic capacitor,” “AND gate,” “NOR gate,” “multiplexer,” and “charge pump.” Terms and basic concepts like these are apparent to those of ordinary skill in the art and thus will not be explained in detail here.

A schematic diagram of a logical signal transmission system 100 is shown in FIG. 1. The system 100 comprises: a driver circuit 110 comprising an inverter 111 for receiving a logical signal D and outputting a source voltage V_{S} to a first circuit node 121; a load 130 comprising a resistor 131 for receiving a load voltage V_{L} from a second circuit node 122; and a transmission line 120 of characteristic impedance Z₀ for providing coupling between the first circuit node 121 and the second circuit node 122. The logical signal D is transmitted by the driver circuit 110 to reach the load 130 via the transmission line 120, resulting in the load voltage V_{L} that is meant to be representative of an inversion of the logical signal D. To ensure good quality of signal transmission, the output impedance of the driver circuit 110, denoted as Z_{S} in FIG. 1, should match well with the characteristic impedance Z₀, and also the input impedance of the load 130, denoted as Z_{L} in FIG. 1, should match well with the characteristic impedance Z₀. In practice, there are always some parasitic capacitors (not shown in FIG. 1, but obvious to those of ordinary skill in the art) present in the transmission path. Said parasitic capacitors slow down the transmission of the logical signal D, and degrade the signal integrity of the load voltage V_{L}.

### BRIEF SUMMARY OF THE INVENTION

In one embodiment, a method comprising receiving a logical signal; driving a source voltage at a first circuit node using a driver circuit; generating an impulsive edge signal by detecting a transition of the logical signal; converting the impulsive edge signal into an impulsive charge pump current using a charge pump circuit; injecting the impulsive charge pump current into the first circuit node; transmitting the source voltage to a second circuit node via a transmission line; and terminating the second circuit node with a load.

### BRIEF DESCRIPTION OF THE DRAWINGS

FIG. 1 shows a schematic diagram of a prior art logical signal transmission system.

FIG. 2A shows a schematic diagram of a logical signal transmission system in accordance with an embodiment of the present invention.

FIG. 2B shows an example timing diagram for the logical signal transmission system of FIG. 2A.

FIG. 3A shows a schematic diagram of an edge detection circuit suitable for use in the logical transmission system of FIG. 2A.

FIG. 3B shows an example timing diagram for the edge detection circuit of FIG. 3A.

FIG. 3C shows a schematic diagram of a programmable delay inverter suitable for use in the edge detection circuit of FIG. 3A.

FIG. 4 shows a schematic diagram of a charge pump circuit suitable for use in the logical transmission system of FIG. 2A.

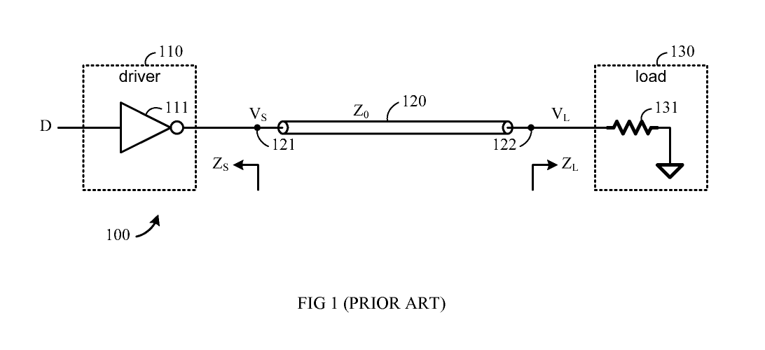

### DETAILED DESCRIPTION OF THE INVENTION

The present invention relates to transmission of logical signals, and in particular, a method and apparatus for ameliorating logical signal transmission by alleviating the degradation of the signal integrity due to undesired parasitic capacitance. An objective of the present invention is to ameliorate logical signal transmission by detecting a logical transition and facilitating the logical transition accordingly. An objective of the present invention is to ameliorate performance of a logical signal transmission system by conditionally injecting an impulsive current into the logical signal transmission system upon detecting a logical transition. An objective of the present invention is to ameliorate performance of a logical signal transmission system by conditionally injecting an impulsive current into the logical signal transmission system upon detecting a logical transition to overcome a slowdown of the logical signal transmission caused by an undesired parasitic capacitor. An objective of the present invention is to ameliorate performance of a logical signal transmission system by conditionally injecting an impulsive current pulse with programmable width and programmable height into the logical signal transmission system upon detecting a logical transition to overcome a slowdown of the logical signal transmission caused by an undesired parasitic capacitor. While the specification describes several example embodiments of the invention considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the invention.

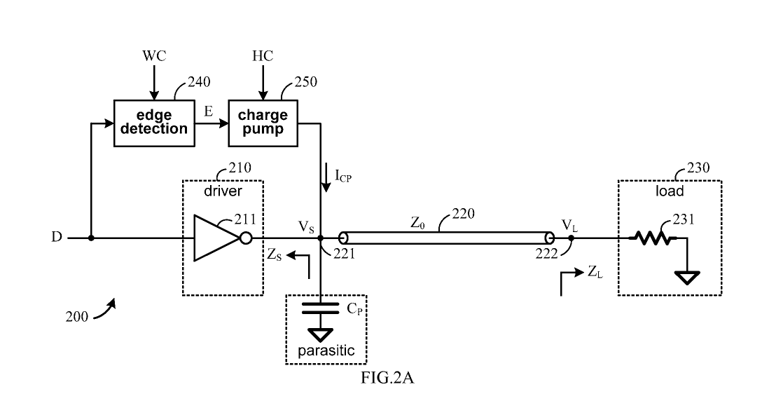

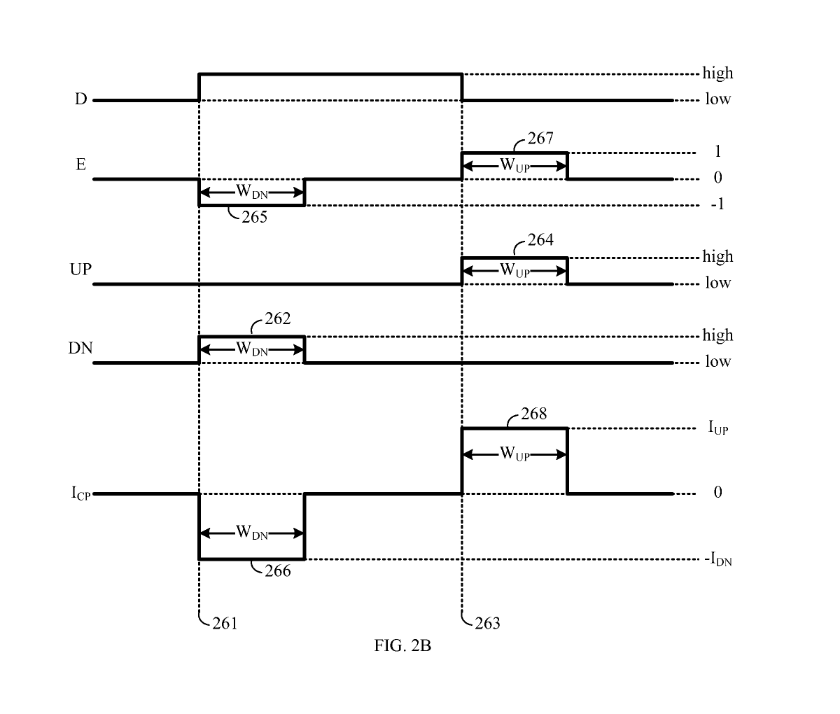

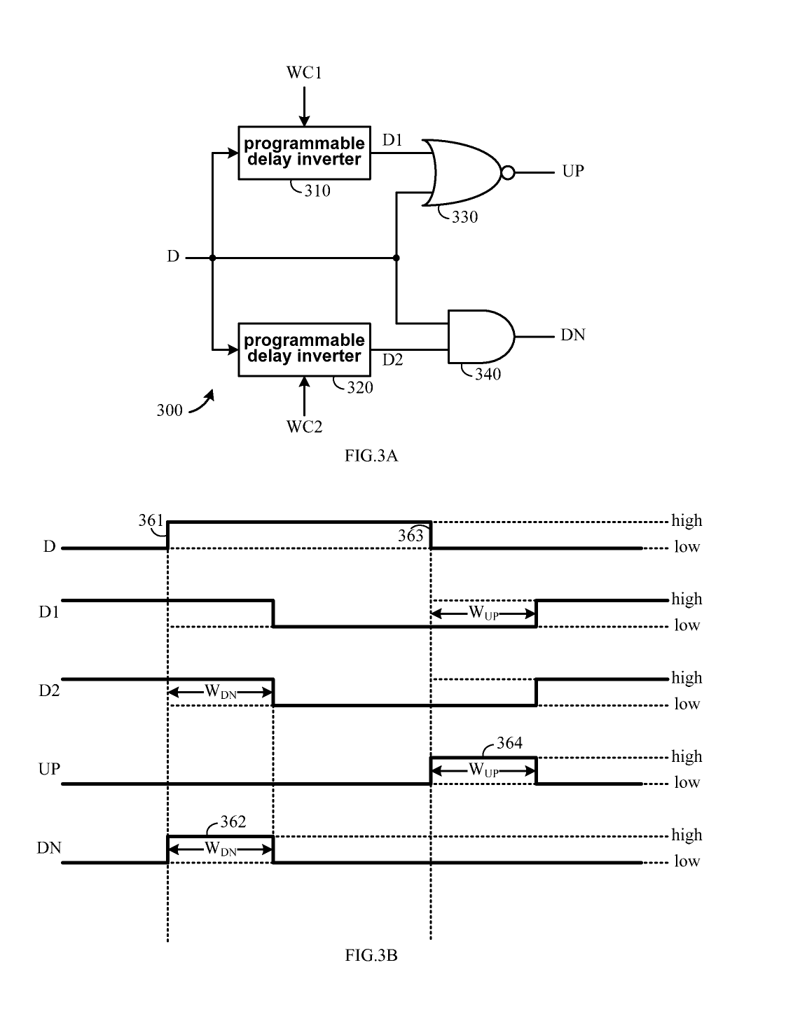

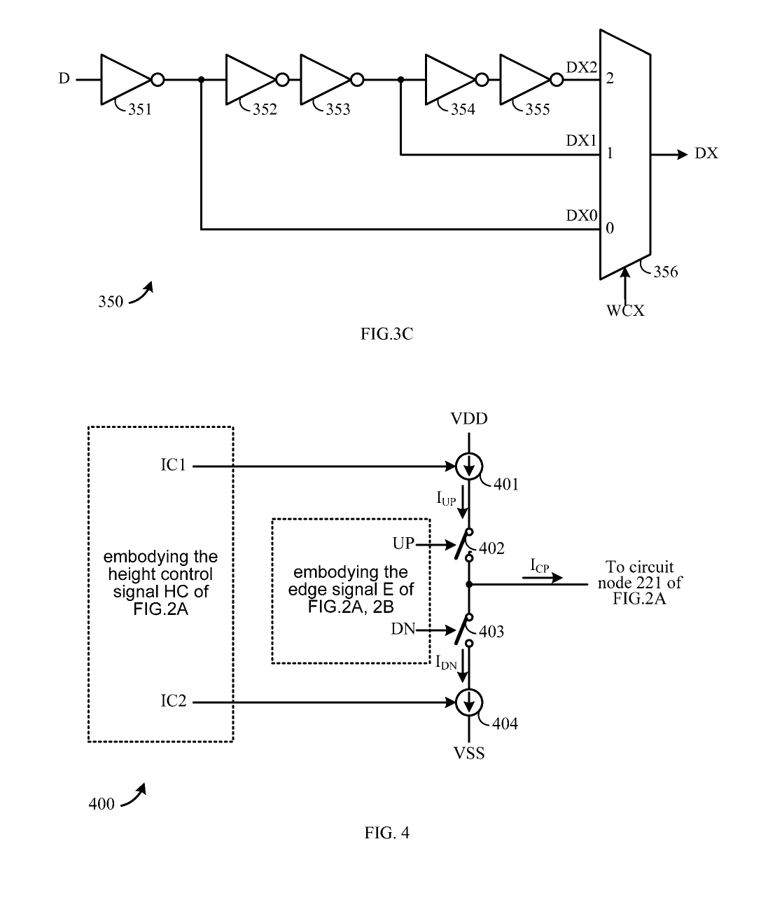

A schematic diagram of a logical signal transmission system 200 in accordance with an embodiment of the present invention is shown in FIG. 2A. The logical signal transmission system 200 comprises: a driver 210 comprising an inverter 211 for receiving a logical signal D and driving a source voltage V_{S} at a first circuit node 221; a load 230 comprising a resistor 231 for receiving a load voltage V_{L} at a second circuit node 222; a transmission line 220 of characteristic impedance Z₀ for providing coupling between the first circuit node 221 and the second circuit node 222; an edge detection circuit 240 for receiving the logical signal D and outputting an edge signal E in accordance with a width control signal WC; and a charge pump circuit 250 for receiving the edge signal E and outputting a charge pump current I_{CP} to the first circuit node 221 in accordance with a height control signal HC. The logical signal D is transmitted by the driver 210 to the load 230 via the transmission line 220, resulting in the load voltage V_{L} that is meant to be a truthful representation of an inversion of the logical signal D. To ensure good quality of the transmission of the logical signal D, both the output impedance Z_{S} of the driver 210 and the input impedance Z_{L} of the load 230 need to approximately match the characteristic impedance Z₀ of the transmission line 220. When the logical signal D makes a low-to-high (high-to-low) transition, the source voltage V_{S} will make a high-to-low (low-to-high) transition. However, the high-to-low (low-to-high) transition of the source voltage V_{S} will be hindered by various parasitic capacitors along the transmission path, where a composite effect of said parasitic capacitors can be modeled by an equivalent parasitic capacitor C_{P} located at circuit node 221. To overcome the hindrance caused by the equivalent parasitic capacitor C_{P}, the charge pump current I_{CP} is generated and injected to the first circuit node 221 so as to facilitate the transition.

In an embodiment, the edge signal E is embodied by two logical signals UP and DN in accordance to a truth table tabulated in Table 1 shown below.

TABLE 1

| E | UP | DN |
|---|---|---|
| 1 | High | Low |
| 0 | Low | Low |
| −1 | Low | High |

An example timing diagram of the logical signal transmission system 200 of FIG. 2A is depicted in FIG. 2B. The logical signal D has two states: low and high. The edge signal E is a “mono-stable” ternary signal that is impulsive in nature and has three states: “1,” “0,” and “−1”. The “0” state is the only stable state, while “1” and “−1” are unstable (i.e., transient) states. Upon arrival of a low-to-high transition of the logical signal D, the edge signal E enters the “−1” state, stays there for a time duration W_{DN}, and then returns to the “0” state. Upon arrival of a high-to-low transition of the logical signal D, the edge signal E enters the “1” state, stays there for a time duration W_{UP}, and then returns to the “0” state. The charge-pump current I_{CP} is a three-level current-mode signal that has three levels: “I_{UP},” 0, and “−I_{DN},” representing the three states of the edge signal E: “1,” “0,” and “−1,” respectively. As shown in FIG. 2B, at timing instant 261, the logical signal D undergoes a low-to-high transition. In response, the edge signal E temporarily enters the “−1” state for the time duration W_{DN} (see the negative pulse 265) embodied by pulse 262 of width W_{DN} of the DN signal, resulting in a negative pulse 266 of width W_{DN} and height I_{DN} for the charge pump current I_{CP}. At timing instant 263, the logical signal D undergoes a high-to-low transition. In response, the edge signal E temporarily enters the “1” state for the time duration W_{UP} (see the positive pulse 267) embodied by pulse 264 of width W_{UP} of the UP signal, resulting in a positive pulse 268 of width W_{UP} and height I_{UP} for the current-mode signal I_{CP}. When the charge pump signal I_{CP} is −I_{DN}, the charge pump circuit 250 draws current from the first circuit node 221 to make it easier for the source voltage V_{S} to make the needed high-to-low transition (see FIG. 2A). When the charge pump current I_{CP} is I_{UP}, the charge pump circuit 250 injects current to the first circuit node 221 to make it easier for the source voltage V_{S} to make the needed low-to-high transition (also see FIG. 2A). The charge pump current I_{CP}, therefore, alleviates the degradation of signal integrity due to parasitic capacitors.

In an embodiment, the width control signal WC of FIG. 2A comprises a combination of a positive (i.e., UP) pulse width control signal WC1 and a negative (i.e., DN) pulse width control signal WC2. In an embodiment, a schematic diagram of an edge detection circuit 300 suitable for embodying the edge detection circuit 240 of FIG. 2A is depicted in FIG. 3A. The edge detection circuit 300 comprises: a first programmable delay inverter 310 for receiving the logical signal D and outputting a first delayed signal D1 in accordance with the positive pulse width control signal WC1; a second programmable delay inverter 320 for receiving the logical signal D and outputting a second delayed signal D2 in accordance with the negative pulse width control WC2; a NOR gate 330 for receiving the logical signal D and the first delayed signal D1 and outputting the UP signal; and an AND gate 340 for receiving the logical signal D and the second delayed signal D2 and outputting the DN signal. An example timing diagram of the edge detection circuit 300 of FIG. 3A is shown in FIG. 3B. The circuit delay of the first programmable delay inverter 310 causes a timing difference of W_{UP} between the logical signal D and the first delay signal D1, where W_{UP} is controlled by the positive (i.e., UP) pulse width control signal WC1. The circuit delay of the second programmable delay inverter 320 causes a timing difference of W_{DN} between the logical signal D and the second delay signal D2, where W_{DN} is controlled by the negative (or DN) pulse width control signal WC2. Due to the logical operation of the AND gate 340 of FIG. 3A, a low-to-high transition of the logical signal D leads to a pulse of width W_{DN} for the DN signal (see rising edge 361 and pulse 362 in FIG. 3B). Due to the logical operation of the NOR gate 330 of FIG. 3A, a high-to-low transition of the logical signal D leads to a pulse of width W_{UP} for the UP signal (see falling edge 363 and pulse 364 in FIG. 3B).

In an embodiment, a schematic of a programmable delay inverter 350 suitable for embodying the programmable delay inverters 310 and 320 of FIG. 3A is depicted in FIG. 3C. By way of example but not limitation, a programmable delay having three programmable values of delay is shown here. Programmable delay inverter 350 comprises cascaded inverters 351˜355 receiving the logical data D and outputting three intermediate signals DX0, DX1, and DX2, and a multiplexer 356 receiving the three intermediate signals DX0, DX1, and DX2 and outputting a multiplexed signal DX in accordance with a control signal WCX, which has three possible values: 0, 1, and 2 for selecting DX0, DX1, and DX2, respectively. When the programmable delay inverter 350 is used for embodying the first programmable delay inverter 310 of FIG. 3A: the control signal WCX is the positive pulse width control signal WC1, and consequently the multiplexed signal DX is the first delay signal D1. When the programmable delay inverter 350 is used for embodying the second programmable delay inverter 320 of FIG. 3A: the control signal WCX is the negative pulse width control signal WC2, and consequently the multiplexed signal DX is the second delay signal D2. In either case, a different value of the control signal WCX leads to selecting a different path from the logical signal D to the multiplexed signal DX and thus a different circuit delay. The programmable delay inverter 350 therefore embodies an inverter function with a programmable delay controlled by either the positive pulse width control signal WC1 or the negative pulse width control signal WC2.

In an embodiment, the pulse width for the UP signal (i.e., W_{UP}) is the same as the pulse width for the DN signal (i.e. W_{DN}); this may be useful for applications wherein the driver circuit 210 of FIG. 2A has symmetrical characteristics, as far as its driving capability for low-to-high transition and high-to-low transition is concerned. In another embodiment, the pulse width for the UP signal (i.e., W_{UP}) is larger than the pulse width for the DN signal (i.e. W_{DN}); this may be useful for applications wherein the driver circuit 210 of FIG. 2A has asymmetrical characteristics, wherein its driving capability for low-to-high transition is weaker than for high-to-low transition. In yet another embodiment, the pulse width for the UP signal (i.e., W_{UP}) is smaller than the pulse width for the DN signal (i.e. W_{DN}); this may be useful for applications wherein the driver circuit 210 of FIG. 2A has asymmetrical characteristics, wherein its driving capability for low-to-high transition is stronger than for high-to-low transition.

In an embodiment, a pulse width of the edge signal E, either W_{UP} or W_{DN}, is a fraction of a unit interval of the logical signal D. For instance, a data rate of the logical signal D is one gigabit per second (1 Gb/s), a unit interval of the logical signal D is one nanosecond (1 ns), and the pulse of the edge signal E is a fraction of one nanosecond, say half nanosecond (0.5 ns).

In an embodiment, the height of the positive pulse of the charge pump current I_{CP} (i.e., I_{UP}) is the same as the height of the negative pulse of the charge pump current I_{CP} (i.e. I_{DN}); this may be useful for applications wherein the driver circuit 210 of FIG. 2A has symmetrical characteristics, as far as its driving capability for low-to-high transition and high-to-low transition is concerned. In another embodiment, the height of the positive pulse of the charge pump current I_{CP} (i.e., I_{UP}) is larger than the height of the negative pulse of the charge pump current I_{CP} (i.e. I_{DN}); this may be useful for applications wherein the driver circuit 210 of FIG. 2A has asymmetrical characteristics, wherein its driving capability for low-to-high transition is weaker than for high-to-low transition. In yet another embodiment, the height of the positive pulse of the charge pump current I_{CP} (i.e., I_{UP}) is smaller than the height of the negative pulse of the charge pump current I_{CP} (i.e. I_{DN}); this may be useful for applications wherein the driver circuit 210 of FIG. 2A has asymmetrical characteristics, wherein its driving capability for low-to-high transition is stronger than for high-to-low transition.

In an embodiment, a schematic diagram of a charge pump circuit 400 suitable for embodying charge pump circuit 250 of FIG. 2A is depicted in FIG. 4. Charge pump circuit 400 comprises: a programmable current source 401 for sourcing current I_{UP} of a magnitude controlled by a first current control signal IC1; a first switch 402 controlled by the UP signal; a second switch 403 controlled by the DN signal; and a programmable current sink 404 for sinking current I_{DN} of a magnitude controlled by a second current control signal IC2. Here, VDD denotes a power supply node, and VSS denotes a ground node. In this embodiment, the height control signal HC of FIG. 2A is embodied by a combination of the first current control signal IC1, which determines the magnitude of the current I_{UP} of the current source 401, and the second current control signal IC2, which determines the magnitude of the current I_{DN} of the current sink 404. Charge pump circuits, including this one (charge pump circuit 400) shown in FIG. 4, are well known and widely used in the prior art and therefore are not described in detail here. Those of ordinary skill in the art can freely choose alternative embodiments that can fulfill the same function illustrated by the timing diagram shown in FIG. 2B, as far as the relationship between the charge pump current I_{CP} and the UP and DN signals is concerned. Also, in FIG. 2B, the negative pulse 266 and the positive pulse 268 of the charge pump current I_{CP} don't need to be rectangular. The function of the charge pump circuit 250 of FIG. 2A is fulfilled as long as the charge pump current I_{CP} injects charge into the first circuit node 221 when the UP signal is asserted, and drains charge from the first circuit node 221 when the DN signal is asserted, regardless of the exact shapes of the negative pulse 266 and the positive pulse 268.

Now refer back to FIG. 2A. Upon detecting a transition of the logical signal D, the edge detection circuit 240 commands the charge pump circuit 250 (via the edge signal from edge detection circuit 240) to either quickly charge or discharge the equivalent parasitic capacitor at the first circuit node 221 via the charge pump current I_{CP}, thus facilitating the transitions that need to take place. The signal integrity of the source voltage V_{S} and accordingly the signal integrity of the load voltage V_{L}, are thus improved and less affected by the slowdown due to the parasitic capacitors. If the charge pump circuit 250 is embodied by the charge pump circuit 400 of FIG. 4, which has high output impedance thanks to using current source 401 and current sink 404, the incorporation of the charge pump circuit 250 does not have remarkable impact on the impedance matching needed at the first circuit node 221. If the charge pump circuit 250 is embodied by an alternative charge pump circuit that doesn't have a high output impedance, the incorporation of the charge pump circuit 250 might have an impact on the impedance matching at the first circuit node 221, but the impact is temporary and limited to only within a time duration, either W_{DN} or W_{UP}. Circuit designers may opt to use the charge pump circuit that does not have high output impedance at their own discretion, if they deem the temporary impact on the impedance matching tolerable.

Note that both the edge signal E and the charge pump current I_{CP} are impulsive in nature, in response to a transition of the logical signal D. This is because the degradation of the signal integrity of the source voltage V_{S} due to the parasitic capacitors occurs mainly when the logical signal D undertakes a transition, where an extra strength of driving is required to either charge or discharge the parasitic capacitors. The needed extra strength of driving is provided by the charge pump circuit 250 in an impulsive manner only when a transition of the logical signal D takes place. By making both the pulse width and pulse height programmable for the charge pump current I_{CP}, an optimum performance based on an optimum combination of the pulse width and the pulse height in accordance with the capacitance of the equivalent parasitic capacitor C_{P} and the data rate of the logical signal D can be achieved. In an embodiment, the pulse height is set to be proportional to the capacitance of the equivalent parasitic capacitor C_{P} and also proportional to the data rate of the logical signal D. By this arrangement, a slew rate of the source voltage V_{S}, which is approximately equal to the magnitude of the charge pump current I_{CP} divided by the capacitance of the equivalent capacitor C_{P}, tracks the data rate of the logical signal D. In an embodiment, the pulse width is set to be inversely proportional to the data rate of the logical signal D.

In an embodiment, the logical transmission system 200 of FIG. 2A is a part of a DDR SDRAM (double data rate synchronous dynamic random access memory) PHY that comprises a parallel bus for transmitting a plurality of logical signals concurrently. By way of example but not limitation, the transmission of a first logical signal among said plurality of logical signals is embodied by the logical transmission system 200 of FIG. 2A, wherein: the capacitance of the equivalent parasitic capacitor C_{P} is 1 pF, a pulse width of the edge signal E (either W_{UP} or W_{DN}) is 200 ps (400 ps), and the height of the charge pump current I_{CP} (either I_{UP} or I_{DN}) is 2 mA (1 mA), when the data rate of the parallel bus is 2000 Mb/s (1000 Mb/s); in the mean while, the transmission of a second logical signal among said plurality of logical signals is embodied by the logical transmission system 200 of FIG. 2A, wherein: the capacitance of the equivalent parasitic capacitor C_{P} is 2 pF, a pulse width of the edge signal E (either W_{UP} or W_{DN}) is 200 ps (400 ps), and the height of the charge pump current I_{CP} (either I_{UP} or I_{DN}) is 4 mA (2 mA). In an alternative embodiment, the transmission of the second logical signal among said plurality of logical signals is embodied by the logical transmission system 200 of FIG. 2A, wherein: the capacitance of the equivalent parasitic capacitor C_{P} is 2 pF, a pulse width of the edge signal E (either W_{UP} or W_{DN}) is 400 ps (800 ps), and the height of the charge pump current I_{CP} (either I_{UP} or I_{DN}) is 2 mA (1 mA). In other words, the parameters (e.g., W_{UP}, W_{UN}, I_{CP}, and I_{DN}) for each logical signal in the parallel bus can be configured individually.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A system comprises:
a driver circuit configured to receive a logical signal and drive a source voltage at a first circuit node;
an edge detection circuit configured to receive the logical signal and output an impulsive edge signal;
a charge pump circuit configured to receive the impulsive edge signal and output an impulsive charge pump current to the first circuit node; and
a load circuit configured to receive a load voltage at a second circuit node, and a transmission line coupling the first circuit node and the second circuit node.

2. The system of claim 1, wherein a width of the impulsive edge signal is a fraction of a unit interval of the logical signal, and is adjustable via a width control signal.

3. The system of claim 2, wherein the edge detection circuit comprises a programmable delay inverter with a delay determinable by the width control signal.

4. The system of claim 2, wherein the width of the impulsive edge signal is adjustable in accordance with a data rate of the logical signal.

5. The system of claim 4, wherein the width of the impulsive edge signal is adjustable to be inversely proportional to the data rate of the logical signal.

6. The system of claim 1, wherein a height of the impulsive charge pump current is adjustable via a height control signal.

7. The system of claim 6, wherein the height of the impulsive charge pump current is adjustable via the height control signal in accordance with an equivalent parasitic capacitance of the system and a data rate of the logical signal.

8. The system of claim 7, wherein the height of the impulsive charge pump current is adjusted so that the height of the impulsive charge pump current divided by the equivalent parasitic capacitance of the system tracks the data rate of the logical signal.

9. The system of claim 1, wherein the impulsive edge signal comprises a combination of a first impulsive logical signal in response to a first kind of transition of the logical signal and a second impulsive logical signal in response to a second kind of transition of the logical signal.

10. The system of claim 9, wherein the charge pump circuit comprises a first kind of charge-pumping circuit controlled by the first impulsive logical signal and a second kind of charge-pumping circuit controlled by the second impulsive logical signal.

11. A method comprising:
receiving a logical signal;
driving a source voltage at a first circuit node using a driver circuit;
generating an impulsive edge signal by detecting a transition of the logical signal;
converting the impulsive edge signal into an impulsive charge pump current using a charge pump circuit;
injecting the impulsive charge pump current into the first circuit node;
transmitting the source voltage to a second circuit node via a transmission line; and
terminating the second circuit node with a load.

12. The method of claim 11 further comprising making a width of the impulsive edge signal adjustable via a width control signal.

13. The method of claim 12 further comprising using a programmable delay inverter with a delay determined by the width control signal to adjust the width of the impulsive edge signal.

14. The method of claim 12, wherein the width of the impulsive edge signal is a fraction of a unit interval of the logical signal, and is adjusted in accordance with a data rate of the logical signal.

15. The method of claim 14, wherein the width of the impulsive edge signal is adjusted to be inversely proportional to the data rate of the logical signal.

16. The method of claim 15, wherein a height of the impulsive charge pump current is adjustable via a height control signal.

17. The method of claim 16, wherein the height of the impulsive charge pump current is adjustable via the height control signal in accordance with an equivalent parasitic capacitance of the system and a data rate of the logical signal.

18. The method of claim 17, wherein the height of the impulsive charge pump current is adjusted so that the height of the impulsive charge pump current divided by the equivalent parasitic capacitance of the system tracks the data rate of the logical signal.

19. The method of claim 11, wherein the impulsive edge signal comprises a combination of a first impulsive logical signal in response to a first kind of transition of the logical signal and a second impulsive logical signal in response to a second kind of transition of the logical signal.

20. The method of claim 19, wherein the charge pump circuit comprises a first kind of charge-pumping circuit controlled by the first impulsive logical signal and a second kind of charge-pumping circuit controlled by the second impulsive logical signal.
